(19) United States
(12) Patent Application Publication
(10) Pub. No.: US 2016/0010170 A1
(43) Pub. Date: Jan. 14, 2016

(54) Ultrathin Alloys

(71) Applicant: ARCANUM ALLOY DESIGN INC., Sunnyvale, CA (US)

(72) Inventors: Adam G. Thomas, Mountain View, CA (US); Daniel E. Bullard, Cupertino, CA (US); Joseph E. McDermott, Sunnyvale, CA (US)

(73) Assignee: ARCANUM ALLOY DESIGN INC., Sunnyvale, CA (US)

(21) Appl. No.: 14/771,896

(22) PCT Filed: Mar. 4, 2014
(86) PCT No.: PCT/US14/20226

§ 371 Date: Sep. 1, 2015

Related U.S. Application Data
(60) Provisional application No. 61/772,564, filed on Mar. 5, 2013.

(51) Int. Cl. C21D 8/02; C22F 1/00; C21D 6/00; C22C 21/00; C22C 38/54; C22C 38/52; C22C 38/50; C22C 38/46; C22C 38/42; C22C 38/04; C22C 38/02; C22C 38/00; C22C 38/06; C25D 7/06; C23C 14/16; C23C 14/34; C22F 1/04

(52) U.S. Cl. CPC C21D 8/0257; C21D 8/0205; C21D 8/0221; C22F 1/04; C22F 1/008; C21D 6/004; C21D 6/005; C21D 6/007; C21D 6/008; C22C 21/00; C22C 38/54; C22C 38/52; C22C 38/50; C22C 38/46; C22C 38/42; C22C 38/04; C22C 38/02; C22C 38/002; C22C 38/06; C25D 7/0614; C23C 14/16; C23C 14/34

(57) ABSTRACT

Herein is described a process for preparing an alloy that includes defining a product composition, thickness, and homogeneity; providing a base that has a thickness less than the product thickness and has a base composition; depositing an alloying material onto at least one surface of the base to yield a coated base that has a composition equal the product composition but has a different homogeneity; and then full thickness annealing the base and the alloying material to provide the product homogeneity. The process can be used to provide ultrathin foils, for example, ultrathin foils of ferrous or aluminum alloys.

### CROSS-REFERENCE

A benefit of priority is claimed to U.S. Provisional Patent Application No. 61/772,564 filed 05 Mar. 2013, the disclosure of which is incorporated herein in its entirety.

### FIELD OF THE INVENTION

This invention is directed to the production of ultrathin sheets, tubes, and forms that comprise metal admixtures and/or alloys and the corresponding products.

### BACKGROUND

The production of thin gauge alloy sheets is commonly accomplished by the repetitive hot rolling and cold rolling of a slab that comprises the alloy composition. Such processes are very common in the steel industry and it is well known that the thinner gauge desired the more expensive the product will become. This increase in expense is due to the increased precision, time, and post rolling processing that needs to be conducted on ever-lengthening sheets of the alloy. Furthermore, the addition of some alloying elements exacerbates the difficulty, and thereby the expense of rolling, by causing the alloy to work hardens. The work hardening adds additional steps (annealing and rolling) and costs to the production of light gauges.

Furthermore, the rolling of metals or alloys that include metals that are reactive toward oxygen and water (e.g., Al, Ti, V, Cr, Fe, Cu, Si) is inhibited by the production of oxides and hydroxides on the rolled surface. For example, rolling steel causes the formation of oxides and hydroxides (e.g., scale) that have different hardnesses than the bulk material. These oxides and/or hydroxides can damage the rolling equipment and/or prevent the material from rolling consistently. As the thickness of the rolled metal or alloy decreases, the scale becomes a greater percentage of the overall product leading to excessive structural problems.

The prior art fails to provide a process for the production of ultrathin alloys.

### SUMMARY

A process comprising: defining a product composition, thickness, and homogeneity; providing a base that has a thickness less than the product thickness and has a base composition; depositing an alloying material onto at least one surface of the base to yield a coated base that has a composition equal the product composition but has a different homogeneity; full thickness annealing the base and the alloying material to provide the product homogeneity.

A process for preparing an ultrathin, ferrous-alloy or aluminum-alloy foil comprising: providing a rolled iron or aluminum base that has a thickness of less than 250 μm, 200 μm, 150 μm, 100 μm, 75 μm, 50 μm, 25 μm, 20 μm, 15 μm, 10 μm, or 5 μm, two major surfaces, and comprises a base composition that includes a majority (wt. %) of iron or aluminum; depositing an alloying material onto a major surface; and then annealing the base and alloying material to provide the ferrous-alloy or aluminum-alloy foil.

A process for preparing an ultrathin, alloy foil that has a thickness in a range of 0.05 μm to 25 μm comprising: providing a rolled base that has a thickness of less than 25 μm, 20 μm, 15 μm, 10 μm, or 5 μm, two major surfaces, and a composition that is substantially free of iron and aluminum; depositing a plurality of deposition metals or non-metals onto a major surface; and then annealing the base and deposited metals or non-metals to provide the alloy foil.

### DETAILED DESCRIPTION

One embodiment of the herein describe process includes defining a product composition, thickness, and homogeneity. That is, the desired product is defined by a series of parameters that include the product composition (e.g., weight percentages of metals and non-metals included in the product; when the product is a metal alloy the product composition includes the weight percentages of the metals and non-metals in the alloy). The product composition can include ranges of weight percentages of elements in the product composition or specific weight percentages (within a standard of error). Preferably, the product composition is defined as an approximate weight percentage of metals and optionally non-metals in the product.

In one example, the product composition is selected from the group consisting of a chromium-iron alloy, a nickel-iron alloy, a chromium-nickel-iron alloy, a manganese-iron alloy, a chromium-manganese-iron alloy, and a chromium-manganese-nickel-iron alloy. Preferably, the product is a stainless steel; that is the product has a composition that includes iron and chromium, optionally nickel as well as other elements known in stainless steel.

The desired product is preferably further defined by the product thickness (as measured in mm or microns). Preferably, the product thickness is less than 10 mm, 9 mm, 8 mm, 7 mm, 6 mm, 5 mm, 4 mm, 3 mm, 2 mm, 1 mm, 0.5 mm, 0.1 mm, 0.05 mm, 0.01 mm or 0.005 mm. For example, the product can have a thickness of about 250 μm, 200 μm, 150 μm, 100 μm, 75 μm, 50 μm, 25 μm, 20 μm, 15 μm, 10 μm, or 5 μm. The desired product is preferably still further defined by the product homogeneity. That is, the desired product is defined as a homogeneous material having an approximately consistent formulation throughout the product or a specific heterogeneity. Examples of heterogeneities include higher concentrations of specific elements at or near surfaces, intermetallics, concentration profiles, or other inconsistencies as available in the product. Preferably, the product is approximately homogeneous, that is the product preferably has a composition that is approximately consistent throughout the material. An alloy that has an approximately consistent composition includes concentrations of each element included in the alloy, where the concentration of an element varies by less than 5%, 4%, 3%, 2%, or 1% across the thickness of the product. Preferably, the concentrations of all of the elements included in the alloy vary by less than 5%, 4%, 3%, 2%, or 1% across the thickness of the product. In select examples, the concentrations of the majority of the elements can be approximately consistent across the thickness of the product while a single element varies by greater than about 5% over the thickness. The product can be further defined by grain structure. Preferably, the product is substantially free of cracking, orange peeling, fracturing and/or plastic deformation. Plastic deformation is the elongation or stretching of the grains in a metal or alloy brought about by the distortion of the metal or alloy. For example, cold rolled steel will display plastic deformation in the direction of the rolling. Plastic deformation in steel is easily observable and quantifiable through the investigation of a cross-section of the steel. Herein, the products are preferably substantially free of plastic deformation; that is the products include less than 15%, 10%, or 5% plastic deformation. More preferably, the products described herein are essentially free of plastic deformation; that is, the products include less than 1% plastic deformation. Even more preferably, the products described herein are free of plastic deformation; that is, plastic deformation in the described products is not observable by investigation of a cross section of the product.

The process includes providing a base; for example, a base coil, sheet or wire. The base (sheet, coil or wire) has a base basethickness that is less than the product thickness. That is, the product and the base have approximately the same shape (e.g., coil, sheet, or wire) where the thickness from one major surface to another major surface (e.g., cross sectional diameter) in the base is less than the defined product thickness. The difference in thicknesses between the base and the product thickness can be less than 0.05 mm or greater than 0.05 mm, 0.1 mm, 0.5 mm or 1 mm. In some examples, the base has a thickness of about 100 μm, 75 μm, 50 μm, 25 μm, 20 μm, 15 μm, 10 μm, or 5 μm. Furthermore, the base has a base composition that includes at least one element of the product composition but can be deficient in concentrations, elements, or both. The base preferably is a rolled metal product. In one instance the base is a cold-worked coil, sheet, or wire. For example, the base can be a cold-rolled, full-hard coil, sheet or wire. In another instance the base can be a hot rolled coil, sheet, or wire. In still another instance the base can be cold rolled and then tempered to release some or all of the work hardening.

The process further includes depositing an alloying material onto at least one surface of the base to yield a coated base that has a composition (e.g., total weight percentages of elements) approximately equal to or equal to the product composition but has a different homogeneity. Notably, the process can include depositing an alloying material to yield a coated base that does not have the product composition. This process would then include depositing an alloying material (same or different) to yield a coated base that has a composition approximately equal to equal to the product composition. The second, or later, depositions of alloying material can occur before or after an annealing step. For example, a first alloying material can be deposited onto the base, the alloying material and the base can be heated to partially or fully anneal the alloying material and base, and then another alloying material can be deposited onto the annealed composition; the process can further include annealing the coated annealed composition.

The deposition of the alloying material can be single pass or step-wise. Furthermore, the deposition of alloying materials can include the code position of individual elements, the deposition of compounds, or the deposition of individual elements. In single pass depositions, the entire amount of the alloying material is provided to the base in a single deposition process. In step-wise depositions, alloying material is provided to the surface, the deposited material can be annealed, rolled, otherwise treated, or not, and then the same or a different alloying materials is provided to the surface. The “build up” of the alloying material provides the coated base thickness. The process of the deposition can be selected from, for example, chemical vapor deposition (CVD), physical vapor deposition (PVD), thermal spray, electrochemical deposition, electroless deposition, and combinations of these processes. For example, the base can be coated by electrodeposition (e.g., electrochemical or electroless deposition of Cr, Ni, Mg, Mn, or Al) and then by CVD (e.g., CVD of Si).

The process of depositing the alloying materials can include the surface preparation of the base. For example, the depositing can include the etching, application of a strike layer, or other standard process for the preparation or cleaning of a base before deposition of a metal coating. In one example, oxide layers on a surface of the base are removed or reduced to provide a surface that is substantially free of oxides.

As previously alluded to, the process further includes annealing the base and the alloying materials. Preferably, the process includes full thickness annealing of the base and the alloying material to provide the product homogeneity. The annealing can be in a single or multiple step/temperature process. Full thickness annealing includes annealing for a sufficient time and at a sufficient temperature to promote diffusion of the alloying material into the base. Preferably, deposited alloying material, during full thickness annealing, diffuses from the surface of the base to the core or opposing surface. More preferably, the concentrations of the elements in the base and alloying material equilibrate to provide a product where the concentrations of the elements vary by less than 5%, 4%, 3%, 2%, or 1% across the thickness of the product.

Another embodiment is a process that includes defining a product composition, and product thickness; providing a base that has a base composition and a base thickness, and wherein the base thickness is less than the product thickness; depositing an alloying material onto at least one surface of the base to yield a coated base that has a composition equal the product composition; and then full thickness annealing the base and the alloying material. In one preferable example, the process includes defining a product composition, and thickness, and homogeneity; providing a base that has a base composition; depositing an alloying material onto at least one surface of the base to yield a coated base that has a composition equal the product composition but has a different homogeneity; and full thickness annealing the base and the alloying material to provide the product homogeneity.

In this embodiment, the base is a metal or metal alloy that can be rolled to the product thickness using less energy than rolling the product composition. The assessment of the amount of energy necessary to roll the metal or metal alloy that provides the base (base composition) and the product composition is based on the rolling and treatment of a slabs (e.g., a slab with nominal thickness of 240 mm and nominal width of 1.5 m) of the two compositions to the product thickness. Notably, the working of metal compositions affects the ease of rolling and some materials. These work-hardened materials need to be annealed/softened before subsequent rollings and the energy necessary to anneal/soften these hardened materials is included in the assessment of the amount of energy necessary to reduce the compositions to the product thickness.

One measure for determining whether a base material can be rolled to the product thickness using less energy than is necessary to roll an alloy having the product composition to the product thickness is a strain hardening coefficient. The stress in a material can be described by the following equation:

σ=K·εⁿ

where σ is the stress of the material, K is the strength coefficient, ε is the strain, and n is the strain hardening coefficient. The stress in the materials can be affected by the heat treatment but, at least theoretically, the coefficients are constant for each composition. The n and K (MPa) values for low carbon steel are 0.21 and 600, for 4340 steel are 0.12 and 2650, 304 stainless steel are 0.44 and 1400, and for 2024 aluminum are 0.17 and 780. Based on these values the 304 stainless steel would require more energy to roll than the low carbon steel. Preferably, the base composition has a lower n (strain hardening coefficient) than the product composition. More preferably, the base composition has a lower n and K than the product composition. Therefore, the embodiment, preferably, includes a product composition that includes a stain hardening coefficient and a base composition that includes a strain hardening coefficient, and, even more preferably, includes a base composition strain hardening coefficient that is less than the product composition strain hardening coefficient.

Another embodiment is a process for preparing a thin, preferably an ultrathin, ferrous-alloy or aluminum-alloy foils. As used herein, ultrathin foils preferable have a thickness in a range of about 0.05 μm to about 25 μm; for example the ultrathin foil can have a thickness of about 25 μm, 20 μm, 15 pm, 10 μm, 5 μm, 1 μm, or 0.5 μm. The process includes providing a rolled iron or aluminum base that has a thickness, preferably, less than 20 μm, 15 μm, 10 μm, 5 pm, 1 μm, or 0.5 μm; that is, the base has a thickness that is less than the thickness of the prepared thin, preferably ultrathin, foil. The base further includes two major surfaces that are parallel or approximately parallel. The base further includes a base composition: that is, the composition of the base. The base composition can include a majority (wt. %) of iron or aluminum. Preferably, when preparing a thin or ultrathin ferrous alloy the base comprises a majority of iron and when preparing an thin or ultrathin aluminum alloy the base comprises a majority of aluminum.

In one example where a ferrous alloy is being prepared, the base composition includes at least 55 wt. % iron, at least 65 wt. % iron, at least 75 wt. % iron, at least 85 wt. % iron, at least 95 wt. % iron, or at least 97.5 wt. % iron. Preferably, the base composition includes less than about 10 wt. %, less than 5 wt. %, or less than 2 wt. % of any one of the elements selected from the group consisting of carbon, silicon, boron, aluminum, phosphorous, titanium, vanadium, chromium, manganese, cobalt, nickel, copper, and zinc. Examples of preferable bases are carbon steels, low carbon steels, or very low carbon steels, the compositions of which are known in the art.

In another example where an aluminum alloy is being prepared, the base composition includes at least 75 wt. % aluminum, at least 85 wt. % aluminum, at least 90 wt. % aluminum, or at least 95 wt. % aluminum. In one example, the base is a commercially available aluminum coil which typically includes less than 1 wt. % of Si, less than 1 wt. % of Fe, less than 1 wt. % of Cu, less than 1 wt. % of Mn, less than 1 wt. % of Mg, less than 1 wt. % of Cr, less than 1 wt. % of Zn, and less than 1 wt. % of Ti.

The process of preparing an ultrathin, ferrous-alloy or aluminum-alloy foils further includes depositing an alloying material onto a major surface of the base. In examples where the base is a coil or sheet, the alloying material can be deposited onto one or both of the major surfaces of the coil or sheet. The process of depositing the alloying material can be any one or a combination of CVD, PVD, thermal spray, electrochemical deposition, electroless deposition, and the like.

The deposited alloying material can be selected from the group consisting of vanadium, chromium, manganese, iron, cobalt, nickel, copper, zinc, niobium, molybdenum, aluminum, boron, carbon, silicon, phosphorous, and a mixture thereof. Dependent on the composition of the base, one or more alloying materials may be used to provide a coated base that has a sufficient quantity (wt. %) of materials to provide a predetermined ferrous-alloy or aluminum alloy composition.

Furthermore and preferably dependent on the thickness of the base and the predetermined thickness of the resultant foil, the alloying material is deposited to a thickness or the deposited alloying material has a thickness in a range of about 20 μm to about 0.005 μm, about 15 μm to about 0.01 μm, about 10 μm to about 0.05 μm, about 5 μm to about 0.1 μm, or about 2 μm to about 0.5 μm. Preferably, the thickness of the deposited alloying material and the thickness of the base approximate a predetermined thickness of the ultrathin foil. When the alloying material is deposited onto a plurality of major surfaces of the base the thickness of the deposited alloying material is a sum of the thickness on the individual surfaces.

The process of preparing the ultrathin, ferrous-alloy or aluminum-alloy foils further includes annealing the base and alloying material to provide the ferrous-alloy or aluminum-alloy foil. The annealing comprises heating the base and alloying material to an annealing temperature for an annealing time and under an annealing atmosphere; wherein the annealing temperature and annealing time are sufficient to provide full thickness diffusion.

The process of preparing the ultrathin, ferrous-alloy or aluminum-alloy foils can further include cold rolling the annealed base and alloying material (the annealed product). The cold rolling can be undertaken to flatten the foil, to affect grain orientation, or to minimally reduce the thickness of the annealed base and alloying material. Preferably, any cold rolling of the annealed product is a skin rolling that includes about 0.25% to 1% reduction in the thickness of the product. In preferable examples, the process is free of any rolling process that reduces the thickness of the coated base (base plus alloying material) and/or the annealed product by greater than about 10%, 9%, 8%, 7%, 6%, 5%, 4%, 3%, or 2% of the unrolled thickness. Most preferably, the process is free of any rolling process that reduces the thickness of the coated base (base plus alloying material) and the annealed product by greater than 5% of the unrolled thickness.

In one example, the ferrous-alloy foil has a composition selected from the group consisting of a stainless steel, an electrical steel, an iron-manganese alloy, and an iron-cobalt alloy. In another example, the aluminum-alloy foil has a composition that includes about 1 to about 10 wt. % of the deposited metal; wherein the composition is selected from the group consisting of about 4 to about 8 wt. % Cu; about 4 to about 9 wt. % Zn, or combinations thereof.

Yet another embodiment is a process for preparing an ultrathin, alloy foil that has a thickness in a range of 0.05 μm to 25 μm. The preparation includes providing a rolled base that has a thickness of less than 25 μm, 20 μm, 15 μm, 10 μm, or 5 μm, two major surfaces, and a composition that is substantially free of iron and aluminum. Preferably, the provided base has less than about 10 wt. %, 5 wt. % or 1 wt. % of iron and/or aluminum. The process further includes depositing a plurality of deposition metals or non-metals onto a major surface; and then annealing the base and deposited metals or non-metals to provide the alloy foil. The deposition metals or non-metals (e.g., alloying material) can include iron and/or aluminum as well as vanadium, chromium, manganese, iron, cobalt, nickel, copper, zinc, niobium, molybdenum, aluminum, boron, carbon, silicon, phosphorous, and a mixture thereof.

1. (canceled)

2. The process of claim 15, wherein the product composition is selected from the group consisting of a chromium-iron alloy, a nickel-iron alloy, a chromium-nickel-iron alloy, a manganese-iron alloy, a chromium-manganese-iron alloy, and a chromium-manganese-nickel-iron alloy.

3. The process of claim 2, wherein the product is a stainless steel.

4. A process for preparing an thin, preferably ultrathin, ferrous-alloy or aluminum-alloy product comprising:
providing a rolled iron or aluminum base that has
a thickness of less than 250 μm, and
comprises a base composition that includes a majority (wt. %) of iron or aluminum;
depositing an alloying material onto a major surface of the base thereby providing a coated base, the coated base having a coated base thickness; and then
annealing the base and alloying material to provide the ferrous-alloy or aluminum-alloy product;
wherein the process is free of any cold rolling that reduces the coated base thickness by greater than about 5%.

5. The process of claim 4, wherein the base composition includes at least 85 wt. % iron; and wherein the base composition includes less than about 10 wt. % of any one of the elements selected from the group consisting of carbon, silicon, boron, aluminum, phosphorous, titanium, vanadium, chromium, manganese, cobalt, nickel, copper, and zinc.

6. The process of claim 4, wherein the alloying material is selected from the group consisting of vanadium, chromium, manganese, iron, cobalt, nickel, copper, zinc, niobium, molybdenum, aluminum, boron, carbon, silicon, phosphorous, and a mixture thereof.

7. The process of claim 4, wherein the deposited alloying material has a thickness in a range of about 20 μm to about 0.005 μm.

8. The process of claim 7, wherein the deposited alloying material is deposited onto both major surfaces; and wherein the thickness of the deposited alloying material is a sum of the thickness on the individual surfaces.

9. The process of claim 4, wherein the annealing comprises heating the base and alloying material to an annealing temperature for an annealing time and under an annealing atmosphere; wherein the annealing temperature and annealing time are sufficient to provide full thickness diffusion.

10. The process of claim 4, further comprising skin rolling the annealed ferrous-alloy or aluminum alloy product.

11. The process of claim 4, wherein the process comprises preparing the ferrous-alloy, and wherein the ferrous-alloy foil has a composition selected from the group consisting of a stainless steel, an electrical steel, an iron-manganese alloy, and an iron-cobalt alloy.

12. The process of claim 4, wherein the process comprises preparing the aluminum-alloy, wherein the aluminum-alloy foil has a composition that includes about 1 to about 10 wt. % of the deposited metal; and wherein the composition is selected from the group consisting of about 4 to about 8 wt. % Cu; about 4 to about 9 wt. % Zn, or combinations thereof.

13. (canceled)

14. A process for preparing an ultrathin, alloy foil that has a thickness in a range of 0.05 μm to 25 μm consisting essentially of:
providing a rolled base that has
a thickness of less than 25 μm,
two major surfaces, and
a composition that is substantially free of iron and aluminum;
depositing a plurality of deposition metals or non-metals onto a major surface; and then
annealing the base and deposited metals or non-metals to provide the alloy foil.

15. A process that comprises:
defining an alloy foil product, the product having a product composition, a product stain hardening coefficient, and a product thickness;
providing a base, the base having a base composition, a base strain hardening coefficient, and a base thickness, wherein the base strain hardening coefficient is less than the product strain hardening coefficient, and wherein the base thickness is less than the product thickness;
depositing an alloying material onto at least one surface of the base to yield a coated base that has a composition equal the product composition; and then
full thickness annealing the base and the alloying material.
